(19) United States
(12) Patent Application Publication
(10) Pub. No.: US 2018/0301869 A1
(43) Pub. Date: Oct. 18, 2018

(54) LIGHT-EMITTING BODY, LIGHT-EMITTING DEVICE, ILLUMINATOR, AND METHOD FOR PRODUCING LIGHT-EMITTING BODY

(71) Applicant: SHARP KABUSHIKI KAISHA, Sakai City, Osaka (JP)

(72) Inventor: YOSUKE MAEMURA, Sakai City (JP)

(21) Appl. No.: 15/766,914

(22) PCT Filed: Jul. 13, 2016
(86) PCT No.: PCT/JP2016/070737

§ 371 Date: Apr. 9, 2018

(30) Foreign Application Priority Data
Nov. 4, 2015 (JP) 2015-217025

(51) Int. Cl. H01S 5/06; C09K 11/77

(52) U.S. Cl. CPC H01S 5/0609; F21Y 2115/30; C09K 11/777; C09K 11/7774

(57) ABSTRACT

Occurrence of luminance unevenness or color unevenness is efficiently reduced. In a light-emitting part (10), a first phosphor layer (La1) containing a first YAG phosphor (3), and a second phosphor layer (La2) containing a second YAG phosphor (2) are stacked on a substrate (1). A particle size of the first YAG phosphor is smaller than a particle size of the second YAG phosphor. The first phosphor layer is arranged on a side far from the substrate, and excitation light (E1) is incident on the first phosphor layer.

### TECHNICAL FIELD

The present invention relates to a light-emitting body or the like that receives excitation light and emits fluorescence.

### BACKGROUND ART

In recent years, there has been actively studied a light-emitting device that uses a semiconductor light-emitting element, for example, a light-emitting diode (LED) or a semiconductor laser (laser diode, LD), as an excitation light source. The light-emitting device uses, as illumination light, fluorescence that is generated by irradiating a light-emitting part containing a phosphor with excitation light that is generated from an excitation light source of the semiconductor light-emitting element. An example of such a light-emitting device may be a light-emitting device described in PTL 1.

PTL 1 discloses a semiconductor light-emitting device provided with a resin layer containing a phosphor provided on a light-emitting element. In this semiconductor light-emitting device, light emitted from the light-emitting element and light whose wavelength is converted by the phosphor are transmitted through the resin layer and are radiated to the outside. Also, PTL 1 discloses a configuration in which a phosphor having a relatively large particle size is arranged on the light-emitting element and a phosphor having a relatively small particle size is dispersed in the resin layer; and a configuration in which the resin layer contains therein a scattering material.

### CITATION LIST

### Patent Literature

PTL 1: Japanese Unexamined Patent Application Publication No. 2009-135136 (published on Jun. 18, 2009)

### SUMMARY OF INVENTION

### Technical Problem

However, with the invention described in PTL 1, if the phosphor is dispersed in the resin layer, heat is generated in the resin layer that is separated from the light-emitting element, and the heat is not efficiently released. Moreover, if the resin layer contains the scattering material, light beams are decreased by multiple scattering, or excitation light not absorbed by the phosphor and reflected by the phosphor is increased.

The present invention is made in light of the above-described problems, and an object of the invention is to provide a light-emitting body capable of efficiently reducing occurrence of luminance unevenness or color unevenness. A second object of the invention is to provide a light-emitting body capable of efficiently releasing the heat generated from a phosphor.

### Solution to Problem

To address the above-described problems, a light-emitting body according to an aspect of the invention includes
a first phosphor layer containing a first phosphor that receives excitation light and emits first fluorescence; and
a second phosphor layer containing a second phosphor that receives the excitation light and emits second fluorescence, in which
the first and second phosphor layers are stacked on a substrate,
a particle size of the first phosphor is smaller than a particle size of the second phosphor, and
the first phosphor layer is arranged on a side far from the substrate, and the excitation light is incident on the first phosphor layer.

Furthermore, to address the above-described problems, a light-emitting body according to another aspect of the invention includes
a first phosphor layer containing a first phosphor that receives excitation light and emits first fluorescence; and
a second phosphor layer containing a second phosphor that receives the excitation light and emits second fluorescence, in which
the first and second phosphor layers are stacked on a substrate,
a particle size of the first phosphor is smaller than a particle size of the second phosphor, and
the first phosphor layer is arranged on the substrate, and the excitation light is incident on the first phosphor layer.

### Advantageous Effects of Invention

According to the aspect of the invention, occurrence of luminance unevenness or color unevenness can be efficiently reduced in light to be emitted. Also, according to the other aspect of the invention, the heat generated from the phosphor can be efficiently released.

### BRIEF DESCRIPTION OF DRAWINGS

FIG. 1 illustrates an outline configuration of a light-emitting part according to Embodiment 1.

FIG. 2 illustrates an outline configuration of an illuminator according to Embodiment 1.

FIG. 3(a) and FIG. 3(b) illustrate an outline configuration of a light-emitting part according to a comparative example of Embodiment 1, and FIG. 3(c) illustrates an outline configuration of the light-emitting part according to Embodiment 1.

FIG. 4 provides illustrations for explaining a difference in projection pattern of illumination light due to a difference in particle size of a phosphor stacked on a substrate, FIG. 4(a) illustrating an experimental result of a light-emitting part according to an example, FIG. 4(b) illustrating an experimental result of a light-emitting part according to a comparative example.

FIG. 5 illustrates an outline configuration of a light-emitting part according to Embodiment 2.

FIG. 6 illustrates an outline configuration of a light-emitting part according to Embodiment 3.

FIG. 7(a) and FIG. 7(b) each illustrate an outline configuration of a light-emitting part according to Embodiment 4.

FIG. 8 illustrates an outline configuration of an illuminator according to Embodiment 5.

FIG. 9 illustrates an outline configuration of a light-emitting part according to Embodiment 5.

### DESCRIPTION OF EMBODIMENTS

### Embodiment 1

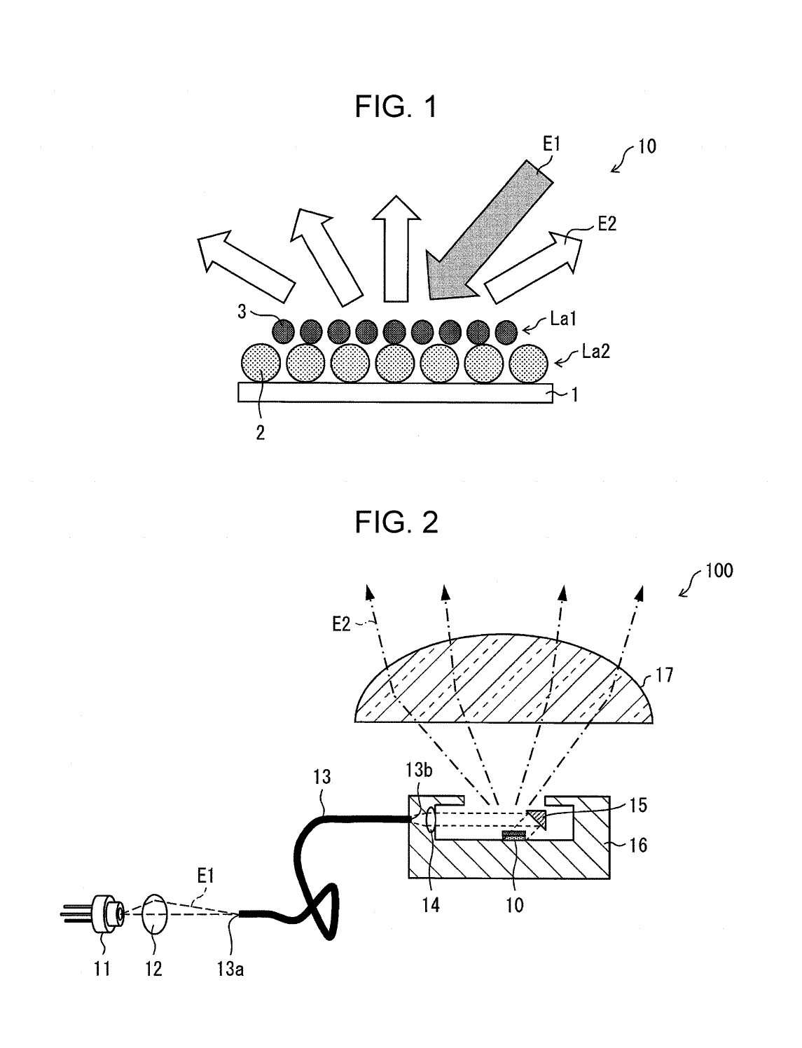

An embodiment of the present invention is described as follows with reference to FIGS. 1 to 4.

### <Outline Configuration of Illuminator 100>

FIG. 2 illustrates an outline configuration of an illuminator 100 according to this embodiment. As illustrated in FIG. 2, the illuminator 100 includes a light-emitting part 10 (light-emitting body), a laser element 11, a first lens 12, an optical fiber 13, a second lens 14, a mirror 15, a casing 16, and a projecting lens 17 (projecting part). The light-emitting part 10 and the laser element 11 form, a basic configuration of a light-emitting device. Also, the light-emitting part 10, the laser element 11, and the projecting lens 17 form a basic configuration of an illuminator.

The illuminator 100 projects illumination light E2 including at least fluorescence that is emitted from the light-emitting part 10 when excited by excitation light E1 emitted from the laser element 11, in a specific direction by the projecting lens 17. While this embodiment is described such that the illumination light E2 includes the excitation light E1 and the fluorescence, only the fluorescence may be projected as the illumination light E2.

Also, the illuminator according to this application can be applied to an illuminator, such as a vehicle headlight (for example, a headlight of an automobile) or a downlight. The downlight is an illuminator installed at a ceiling of a structure, such as a house or a conveyance. Alternatively, the illuminator according to this application may be provided as a headlamp of a mobile object other than the vehicle (for example, person, ship, aircraft, submarine, or rocket), or may be provided as a search light, a projector, or indoor illumination equipment (stand lamp etc.) other than the downlight.

The laser element 11 is an excitation light source that emits the excitation light E1 (laser light) that excites a first phosphor and a second phosphor contained in the light-emitting part 10. The laser element 11 is excitation light of blue light having a peak wavelength in an oscillation wavelength range from 440 nm to 450 nm (or 490 nm or shorter). In this embodiment, the excitation light E1 to be emitted has, for example, a peak wavelength of 450 nm.

The oscillation wavelength range may be appropriately selected in accordance with the kinds of the first phosphor and the second phosphor contained in the light-emitting part 10 (that is, the excitation wavelengths of the first phosphor and the second phosphor). For example, the wavelength range of visible light can be selected. Also, while the single laser element 11 is provided in this embodiment, the number of laser elements 11 may be determined in accordance with, for example, the output. The output of the laser element 11 may be appropriately selected in accordance with the specifications of the illuminator 100. If a plurality of laser elements 11 are used, the excitation intensity can be increased.

Also, for example, an LED may be used as the excitation light source according to this specification.

Although not illustrated, the laser element 11 includes an electrode terminal. A wire is connected to the electrode terminal. The laser element 11 is connected to a power supply circuit for driving, via the wire and the electrode terminal. Further, although not illustrated, to release the heat generated during operation of the laser element 11, a heat releasing mechanism, such as a heat sink or a cooling jig, may be provided for the laser element 11. For the heat releasing mechanism, a metal material, such as aluminum, having high heat conductivity may be used.

The first lens 12 condenses the excitation light E1 emitted from the laser element 11. Then, the excitation light E1 condensed by the first lens 12 is incident on an incidence end 13a of the optical fiber 13. That is, the first lens 12 functions as a light guide member that guides the excitation light E1 to the optical fiber 13. In other words, the laser element 11 is optically coupled to the optical fiber 13 via the first lens 12.

The optical fiber 13 is a light guide member that guides the excitation light E1 emitted from the laser element 11 to the mirror 15 via the second lens 14. The optical fiber 13 has the incidence end 13a that receives the excitation light E1 emitted from the laser element 11, and an emission end 13b that emits the excitation light E1 incident from the incidence end 13a. The excitation light E1 condensed by the first lens 12 is emitted from the emission end 13b of the optical fiber 13, transmitted through the second lens 14, and emitted to the mirror 15.

If a plurality of laser elements 11 exist, incidence ends 13a of the plurality of optical fibers 13 may be provided so as to face corresponding laser elements 11. The plurality of optical fibers 13 may be, for example, a fiber bundle. Alternatively, even if the plurality of laser-elements 11 exist, a single optical fiber 13 may be employed. In this case, excitation light E1 emitted from the plurality of laser elements 11 may be coupled to the single optical fiber 13 by using members, such as a lens and a mirror. For a light guide member that optically couples the laser-element 11 and the light-emitting part 10 to one another, a member other than the optical fiber 13 may be used. The kind of the light guide member is not limited.

The second lens 14 is a light guide member that controls the excitation light E1 emitted from the emission end 13b of the optical fiber 13 so as to be substantially parallel light, and guides the substantially parallel light to the mirror 15. That is, the optical fiber 13 is optically coupled to the mirror 15 via the second lens 14.

The mirror 15 reflects the excitation light E1 transmitted through the second lens 14, and causes the excitation light E1 to be incident on the light-emitting part 10. The mirror 15 is arranged in such a manner that the reflected excitation light E1 is incident on the light-emitting part 10.

The light-emitting part 10 receives the excitation light E1 reflected by the mirror 15 and emits fluorescence. To be specific, the light-emitting part 10 emits fluorescence because the first phosphor and the second phosphor contained in the light-emitting part 10 are excited by the excitation light E1. The detailed configuration of the light-emitting part 10 will be described later.

Alternatively, the excitation light E1 emitted from, the laser element 11 may be directly incident on the light-emitting part 10 without passing through the first lens 12, the optical fiber 13, and the second lens 14.

The casing 16 mainly supports the light-emitting part 10, the second lens 14, and the mirror 15. The material of the casing 16 may be, for example, aluminum. In this case, the heat generated from the light-emitting part 10 can be efficiently released to the outside of the casing 16. Alternatively, the casing 16 may be formed by coating a member made of a certain member, such, as copper (Cu), stainless steel, or magnesium (Mg), with silver (Ag) or aluminum (Al).

The projecting lens 17 is a projecting member (projection optical system) that projects the illumination light E2 including at least the fluorescence emitted from the light-emitting part 10 to the outside. The projecting lens 17 is arranged to face the light-emitting part 10. The projecting lens 17 projects the illumination light E2 emitted from the light-emitting part 10 in a predetermined angle range by refracting the illumination light E2. In this embodiment, the illumination light E2 including the fluorescence and the excitation light E1 scattered by the light-emitting part 10 is projected by the projecting lens

In this embodiment, a convex lens is used as the projecting lens 17. The projecting lens 17 may be either of a spherical lens and an aspherical lens. The material of the projecting lens 17 is appropriately selected from, for example, acrylic resin, polycarbonate, silicon resin, borosilicate glass, BK7, and quartz. The projecting lens 17 may be a single lens as illustrated in FIG. 2 or a plurality of lenses.

The projection optical system may have another configuration, such as a projector type configuration using both a mirror and a convex lens, or a configuration using a reflector (concave mirror), instead of the projecting lens 17. The reflector is, for example, a parabolic mirror (parabolic reflector) having a reflective curved surface including at least a portion of a partial curved surface that is obtained by cutting a reflective curved surface which is defined by rotating a parabola around a symmetric axis of the parabola as a rotation axis, in a plane parallel to the rotation axis. If the reflector is used as the projection optical system, the light-emitting part 10 is arranged at a substantially focal position of the reflector.

### <Specific Configuration of Light-Emitting Part 10>

Next, a specific configuration of the light-emitting part 10 is described with reference to FIG. 1. FIG. 1 illustrates an outline configuration of the light-emitting part 10 of reflective type. As illustrated in FIG. 1, the light-emitting part 10 includes a substrate 1, and a phosphor film including a first phosphor layer La1 and a second phosphor layer La2.

The first phosphor layer La1 is a layer containing a particulate first phosphor that receives the excitation light E1 and emits first fluorescence. The second phosphor layer La2 is a layer containing a particulate second phosphor that receives the excitation light E1 and emits second fluorescence. The first phosphor layer La1 and the second phosphor layer La2 are stacked on the substrate 1. That is, the light-emitting part 10 has a double-layer structure.

In this embodiment, as illustrated in FIG. 1, the first phosphor layer La1 and the second phosphor layer La2 are stacked on the substrate 1 in that order from an incidence side of the excitation light E1. That is, the first phosphor layer La1 is arranged on a side far from the substrate 1. The excitation light E1 is incident on a surface of the first phosphor layer La1 (an upper surface of the first phosphor layer La1) on a side opposite to a surface of the first phosphor layer La1 facing the second phosphor layer La2. Then, the illumination light E2 including the first fluorescence and the second fluorescence is emitted from the upper surface of the first phosphor layer La1. That is, in the light-emitting part 10, the surface on which the excitation light E1 is mainly incident and the surface from which the fluorescence is mainly emitted to the outside are the same surface. In this application, such a light-emitting part is called a “reflective-type” light-emitting part.

For the first phosphor and the second phosphor, for example, an oxynitride-based phosphor (for example, SiALON phosphor) may be used. The oxynitride-based phosphor has high heat resistance against laser light with high output (and/or optical density) emitted from the laser element 11, and hence is optimal for a laser illumination light source. Alternatively, for the first phosphor and the second phosphor, a YAG-based (yttrium-aluminum-garnet-based) phosphor may be used. Still alternatively, a nitride phosphor or the like may be used as the first phosphor and the second phosphor.

In this embodiment, the first phosphor and the second phosphor each are a yellow luminescent phosphor that emits yellow light, which is a YAG-based phosphor (for example, YAG:Ce phosphor). The YAG:Ce phosphor emits yellow fluorescence with a peak wavelength of about 550 nm. In this embodiment, the first phosphor is named first YAG phosphor 3. Also, the second phosphor is named second YAG phosphor 2. Alternatively, a Ca-α-SiAlON:Eu phosphor may be used as the first phosphor and the second phosphor being the yellow luminescent phosphor.

In this embodiment, the light-emitting part 10 contains the first YAG phosphor 3 and the second YAG phosphor 2. By irradiating the first YAG phosphor 3 and the second YAG phosphor 2 with excitation light E1 of 450 nm (blue) (or excitation light E1 of near blue having a peak wavelength in a wavelength range from 440 nm to 490 nm), white light (so-called quasi white light) as the illumination light E2 can be obtained. For example, the illumination light of a headlamp; has to be white having a chromaticity in a prescribed range. This is determined by law. The illuminator 100 can transmit white light as the illumination light E2, and hence the illuminator 100 can be applied as a headlamp (vehicle headlight).

The first phosphor and the second phosphor do not have to be of the same kind, and may be phosphors of two or more kinds. For example, although described later according to Embodiment 2, the light-emitting part 10 may contain a green luminescent phosphor and a red luminescent phosphor, and the white light may be obtained by irradiating the phosphors with the excitation light E1 of blue or near blue. Also, the light-emitting part 10 may contain blue, green, and red phosphors, and by irradiating the phosphors with excitation light E1 of 405 nm (that is, blue violet excitation light), white light may be generated as the illumination light E2. In this case, the laser element 11 emits blue violet excitation light. Also, in this case, by providing a filter that cuts the excitation light E1 of 405 nm, the illumination light E2 that is emitted from the light-emitting part 10 may contain only the fluorescence excited by the light-emitting part 10.

Also, the white light as the illumination light E2 does not have to be emitted from the light-emitting part 10. That is, the oscillation wavelength range of the laser element 11, and the kinds of the first phosphor and the second phosphor are appropriately selected so that the illumination light E2 of a color that is required for a light-emitting device can be emitted.

Also, particles of the first YAG phosphor 3 are preferably bound to one another, particles of the second YAG phosphor 2 are preferably bound to one another, and the second YAG phosphor 2 and the substrate 1 are preferably bound to one another by a binding material (binder). That is, the first YAG phosphor 3 and the second YAG phosphor 2 are preferably coated with the binding material. Accordingly, adhesion between the particles of the first YAG phosphor 3, adhesion between the particles of the second YAG phosphor 2, and adhesion between the second YAG phosphor 2 and the substrate 1 are increased.

The binding material is preferably made of an inorganic transparent material with high heat resistance. For example, the material of the binding material may be SiO₂ (silicon dioxide) or TiO₂ (titanium dioxide). If an inorganic material is used for the binding material, the first phosphor layer La1 and the second phosphor layer La2 can be fabricated so as not to contain an organic substance. The characteristics of the light-emitting part 10 can be prevented from being deteriorated due to the irradiation with the excitation light E1.

In this embodiment, because of the coating with the binding material, the particles of the first YAG phosphor 3 do not directly contact one another, the particles of the second YAG phosphor 2 do not directly contact one another, and the second YAG phosphor 2 and the substrate 1 do not contact one another. However, the configuration is not limited thereto. For example, the substrate 1 and the second YAG phosphor 2 may directly contact one another, and the first YAG phosphor 3 and the second YAG phosphor 2 may directly contact one another.

Further, in this embodiment, after the coating with the binding material, a gap is formed between the particles of the first YAG phosphor 3, a gap is formed between the particles of the second YAG phosphor 2, and a gap is formed between the second YAG phosphor 2 and the substrate 1. In the case of this configuration, the excitation light E1 and the fluorescence are likely scattered due to a difference in refractive index between the phosphor and the air in the gap. However, if this point is not considered, the gap may be completely filled with the binding material.

Also, in this embodiment, as illustrated in FIG. 1, the particle size of the first YAG phosphor 3 arranged on the incidence side of the excitation light E1 is smaller than the particle size of the second YAG phosphor 2 arranged on the side near the substrate 1. The particle size of the first YAG phosphor 3 having a relatively small particle size is, for example, preferably in a range from 1 μm to 10 μm. If the particle size of the first YAG phosphor 3 is smaller than 1 μm, luminous efficiency tends to be decreased. In contrast, particularly if the particle size of the first YAG phosphor 3 is equal to or smaller than 10 μm, the incident excitation light E1 and the illumination light E2 to be emitted can be efficiently scattered.

In this case, the particle size in this application indicates a median size (d50). The median size is a particle size when phosphors are divided into two groups on the basis of the particle size (particle diameter) and when the group with large particle sizes and the group with small particle sizes have equivalent amounts of the phosphors. The particle size of the first YAG phosphor 3 and the particle size of the second YAG phosphor 2 can be discriminated from one another by observing cross sections of the phosphors perpendicular to the substrate 1 by using an electronic microscope or the like. In particular, the particle size of the first YAG phosphor 3 arranged on the side far from the substrate 1 can be discriminated by observing the phosphors in a direction perpendicular to the substrate 1 by using an electronic microscope or the like.

The substrate 1 is supported by the first phosphor layer La1 and the second phosphor layer La2. The substrate 1 is preferably made of, for example, metal or ceramics. In this case, the heat generated from, the first phosphor layer La1 and the second phosphor layer La2 can be efficiently released. Also, the substrate 1 is preferably made of, for example, aluminum or silver, having high reflectivity of light among metal. In this case, the excitation light E1 that is not absorbed by the first phosphor layer La1 and the second, phosphor layer La2 can be efficiently emitted toward the first phosphor layer La1 and second phosphor layer La2 again, in addition to the heat release effect. Hence, efficiency of using the excitation light E1 by the light-emitting part 10 can be increased.

If the second YAG phosphor 3 directly contacts the substrate 1, the heat generated from the first phosphor-layer La1 and the second phosphor layer La2 can be more efficiently released to the substrate 1. If the first YAG phosphor 2 directly contacts the second YAG phosphor 3, the heat generated from the first phosphor layer La1 can be further efficiently released to the substrate 1.

Also, the size of the substrate 1 when viewed from the incidence side of the excitation light E1 is equal to the size of the first phosphor layer La1 and the second phosphor layer La2, or larger than the size of the first phosphor layer La1 and the second phosphor layer La2.

In the light-emitting part 10 according to this embodiment, the blue light serving as the excitation light E1 is emitted on the first phosphor layer La1 containing the first YAG phosphor 3 having a relatively small particle size. In the first phosphor layer La1, the first YAG phosphor 3 absorbs the excitation light E1, and emits yellow-fluorescence serving as first fluorescence. Then, in the second phosphor layer La2 containing the second YAG phosphor 2 having a relatively large particle size, the second YAG phosphor 2 absorbs the excitation light E1 not absorbed by the first YAG phosphor 3 and the excitation light E1 reflected by the substrate 1, and emits yellow fluorescence serving as second fluorescence. (1) The excitation light E1 not absorbed by the first YAG phosphor 3 and the second YAG phosphor 2, and (2) the yellow fluorescence serving as the first fluorescence and the second fluorescence are mixed and the illumination light E2 serving as quasi white light is emitted from the first phosphor layer La1.

When the excitation light E1 is incident on the light-emitting part 10, and when the illumination light E2 is emitted from the light-emitting part 10, the excitation light E1 and the illumination light E2 are emitted on the first YAG phosphor 3 contained in the first phosphor layer La1 and having a relatively small particle size. Also, since the particle size of the first YAG phosphor 3 is smaller than the particle size of the second YAG phosphor 2, the gap between the particles of the first YAG phosphor 3 in the first phosphor layer La1 is smaller than the gap between the particles of the second YAG phosphor 2 in the second phosphor layer La2. Hence, the above-described excitation light E1 and illumination light E2 can be efficiently scattered. Accordingly, occurrence of color unevenness can be efficiently reduced in the illumination light E2 that is emitted from the light-emitting part 10.

Also, if the kinds of the first phosphor and the second phosphor constituting the light-emitting part 10 are the same kind and only the fluorescence excited by the excitation light E1 is emitted from the light-emitting part 10, occurrence of luminance unevenness can be efficiently reduced in the illumination light E2 emitted from the light-emitting part 10 and containing only the fluorescence.

### <Method for Producing Light-emitting Part 10>

Next, a method for producing the light-emitting part 10 is described. The light-emitting part 10 is produced by, for example, sedimentation.

In the sedimentation, the first YAG phosphor 3 and the second YAG phosphor 2 are charged into a solvent (for example, ethanol), the resultant is stirred, and hence slurry is prepared. At this time, a dispersant and a binder may be added and mixed. Then, the substrate 1 is dipped in the slurry in which the first YAG phosphor 2 and the second YAG phosphor 3 are dispersed, and hence the first YAG phosphor 2 and the second YAG phosphor 3 are deposited on the substrate 1. By adding and mixing the dispersant, the sedimentation speed of the first YAG phosphor 2 and the second YAG phosphor 3 can be decreased, and the thicknesses of the first phosphor layer La1 and the second phosphor layer La2 can be easily controlled. Also, by adding and mixing the binder, the adhesion between the first phosphor layer La1 and the second phosphor layer La2 is increased. Then, the substrate 1 on which the first YAG phosphor 2 and the second YAG phosphor 3 are deposited is taken out from the slurry, and dried. Then, to increase the adhesion between the particles of the first YAG phosphor 2, the adhesion between the particles of the second YAG phosphor 3, and the adhesion between the second YAG phosphor 2 and the substrate 1, the first YAG phosphor 2 and the second YAG phosphor 3 are coated with the above-described binding material.

In general, the sedimentation speed depends on the density and particle size of a phosphor contained in a light-emitting part. In the case of a phosphor of the same kind, the density of the phosphor in the light-emitting part is substantially uniform, and hence particles of the phosphor with a larger particle size are more likely deposited on the side near the substrate.

In this embodiment, the first YAG phosphor 2 and the second YAG phosphor 3 of the same kind are used. Hence, the second YAG phosphor 2 having a relatively large particle size is stacked on the substrate 1, and then the first YAG phosphor 3 having a relatively small particle size is stacked on the second YAG phosphor 2. Accordingly, as illustrated in FIG. 1, the second phosphor layer La2 containing the second YAG phosphor 2 is formed on the side near the substrate 1, and the first phosphor layer La1 containing the first YAG phosphor 3 is formed on the side far from the substrate 1 (that is, the incidence side of the excitation light E1).

In the above-described sedimentation, the first YAG phosphor 3 and the second YAG phosphor 2 having different particle-size distributions are mixed in the slurry in advance; however, it is not limited thereto.

For example, the second YAG phosphor 2 having a relatively large particle size is dispersed in slurry. Then, the substrate 1 is clipped in the slurry in which the second YAG phosphor 2 is dispersed, and hence the second YAG phosphor 2 is deposited on the substrate 1. Thereafter, the substrate 1 on which the second YAG phosphor 2 is deposited is taken out from the slurry, and dried.

Then, the first YAG phosphor 3 having a relatively small particle size is dispersed in slurry. Then, the substrate 1 on which the second YAG phosphor 2 is deposited is dipped in the slurry in which the first YAG phosphor 3 is dispersed, and hence the first YAG phosphor 3 is deposited on the second YAG phosphor 2. Then, the substrate 1 on which the first YAG phosphor 3 and the second YAG phosphor 2 are deposited is taken out from the slurry, and dried.

Like the above-described process, the first YAG phosphor 3 and the second YAG phosphor 2 are coated with the binding material. The coating using the binding material may be performed as follows. For example, after the second YAG phosphor 2 is deposited and hence the second phosphor layer La2 (first phosphor layer) is formed, the second YAG phosphor 2 is coated with the binding material. Then, after the first YAG phosphor 3 is deposited on the second phosphor layer La2 and hence the first phosphor layer La1 (second phosphor layer) is formed, the first YAG phosphor 3 is coated with the binding material.

In electrophoresis, the first YAG phosphor 3, the second YAG phosphor 2, and a dispersant are charged into a solvent, and hence slurry is prepared. At this time, a binder may be added and mixed. By adding and mixing the binder, the adhesion between the first phosphor layer La1 and the second phosphor layer La2 is increased. First, two electrodes are arranged at upper and lower positions in the slurry, and the substrate 1 is arranged as the lower electrode. Then, a voltage is applied in such a way that the first YAG phosphor 3 and the second YAG phosphor 2 are deposited on the substrate 1. At this time, the substrate 1 is preferably made of metal because the substrate 1 needs to be conductive. The first YAG phosphor 3 and the second YAG phosphor 2 are settled simultaneously when moved due to an electric field. Hence, the second phosphor layer La2 containing the second YAG phosphor 2 is formed on the side near the substrate 1, and the first phosphor layer La1 containing the first YAG phosphor 3 is formed on the side far from the substrate 1 (that is, the incidence side of the excitation light E1).

In the above-described electrophoresis, the first YAG phosphor 3 and the second YAG phosphor 2 having different particle-size distributions are mixed in the slurry in advance; however, it is not limited thereto. The first YAG phosphor 3 and the second YAG phosphor 2 may be prepared in different slurry, and deposited at different timing like the sedimentation. Alternatively, the method for producing the light-emitting part 10 may be provided by screen printing, application using a dispenser, or another method, without limiting to the sedimentation and the electrophoresis.

In the screen printing, first, a screen mask having a mesh made of synthetic fiber or metal fiber is arranged on the substrate 1, ink containing the second YAG phosphor 2 is discharged by a squeegee via the mesh, and hence the second phosphor layer La2 is formed on the substrate 1. Then, a screen mask is arranged on the second phosphor layer La2, ink containing the first YAG phosphor 3 is discharged via the mesh, and hence the first phosphor layer La1 is formed on the second phosphor layer La2. Also, a metal mask without a mesh may be used as a screen mask. This case is more preferable because a mark of the mesh does not remain on the first phosphor layer La1 and the second phosphor layer La2. The ink contains phosphor particles including the first YAG phosphor 3 and the second YAG phosphor 2, an organic solvent serving as a dispersion medium, a resin for increasing viscosity, and a dispersing material. Organic components other than the phosphor particles are eliminated by firing at high temperature after the application by printing. By coating the first phosphor layer La1 and the second phosphor layer La2 with a binding material after the firing, the adhesion between the first phosphor layer La1 and the second phosphor layer La2 is increased. The binding material may be added to the ink in advance, and the resultant may be applied by printing.

In the application method using the dispenser, first, an organic solvent in which the second YAG phosphor 2 is dispersed is discharged from, the dispenser, and hence the second phosphor layer La2 is formed on the substrate 1. Then, a solvent in which the first YAG phosphor 3 is dispersed is discharged from, the dispenser, and hence the first phosphor layer La1 is formed on the second phosphor layer La2. Then, the resultant is fired at high temperature, and hence organic components are eliminated. By coating the first phosphor layer La1 and the second phosphor layer La2 with a binding material after the firing, the adhesion between the first phosphor layer La1 and the second phosphor layer La2 is increased.

In particular, when the light-emitting part 10 is produced by using the sedimentation or the electrophoresis, such a method is desirable because the first phosphor layer La1 and the second phosphor layer La2 can be simultaneously deposited.

### <Advantageous Effects of Light-Emitting Part 10>

In the light-emitting part 10 according to this embodiment, the first phosphor layer La1 containing the first YAG phosphor 3 having a smaller particle size than the particle size of the second YAG phosphor 2 is arranged on the side far from the substrate 1. The excitation light E1 is incident on the first phosphor layer La1. Accordingly, as described above, occurrence of luminance unevenness or color unevenness can be efficiently reduced in the illumination light E2 that is emitted from the light-emitting part 10.

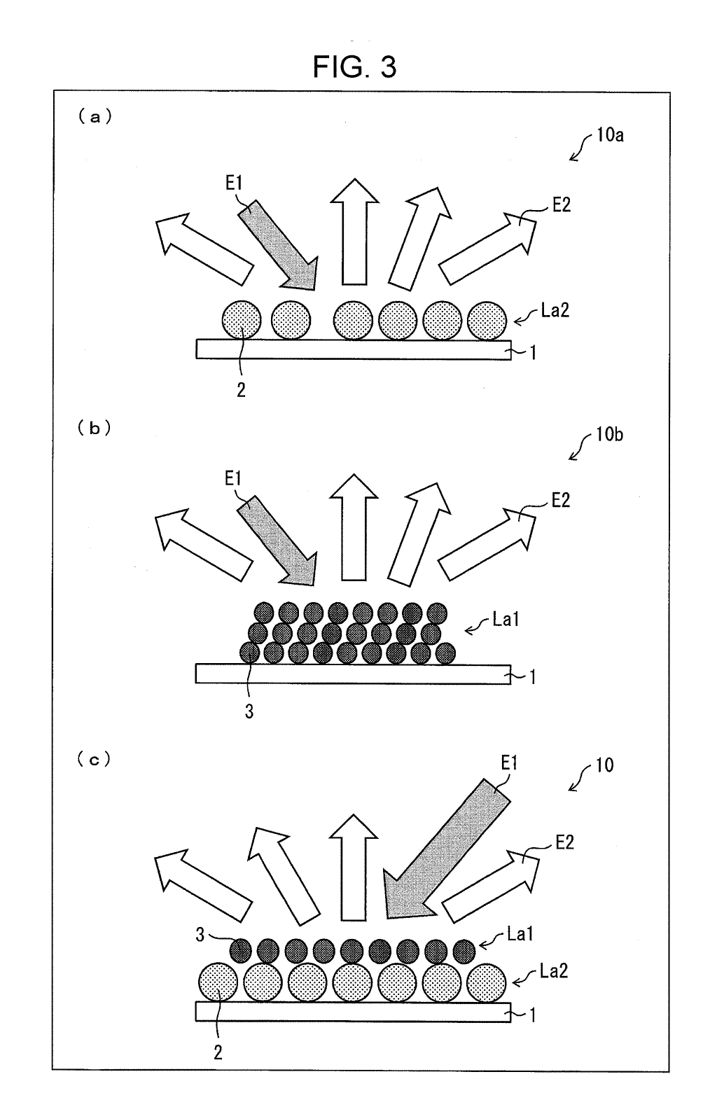

Also, with the light-emitting part 10 according to this embodiment, the problems that arise in the conventional light-emitting device can be addressed. This point is described with reference to FIG. 3(a) to FIG. 3(c). FIG. 3(a) illustrates an outline configuration of a light-emitting part 10a according to a comparative example of this embodiment, in which only the second phosphor layer La2 is arranged on the substrate 1. That is, in the light-emitting part 10a, only the second YAG phosphor 2 having a relatively large particle size is stacked on the substrate 1. FIG. 3(b) illustrates an outline configuration of a light-emitting part 10b according to a comparative example of this embodiment, in which only the first phosphor layer La1 is arranged on the substrate 1. That is, only the first YAG phosphor 3 having a relatively small particle size is stacked. FIG. 3(c) illustrates an outline configuration of the light-emitting part 10 according to this embodiment.

As illustrated in FIG. 3(a), since the light-emitting part 10a uses only the second YAG phosphor 2 having a relatively large particle size, the absorption index of the excitation light E1 being incident on the second YAG phosphor 2 is higher than that of the light-emitting part 10b. Hence, luminous efficiency with respect to the excitation light E1 is higher than that of the light-emitting part 10b. However, when the excitation light E1 is incident on the light-emitting part 10, and when the illumination light E2 is emitted from the light-emitting part 10, the excitation light E1 and the illumination light E2 are less likely scattered.

Also, in general, if the absorption index of excitation light is high, it is required to decrease the density of fluorescence contained in a light-emitting part in order to obtain a desirable color for illumination light. Since the light-emitting part 10a has high absorption index of the excitation light E1, it is required to decrease the density of the second YAG phosphor: 2 contained in the second phosphor layer La2. Hence, the gap between the second phosphor layers La2 is increased, the excitation light E1 and the yellow fluorescence are less likely mixed, and color unevenness in the illumination light E2 becomes noticeable.

Further, since the gap is increased, the surface of the substrate 1 is exposed, and the surface may be viewed from the incidence side of the excitation light E1 (that is, the emission side of the illumination light E2). In this case, the excitation light E1 directly emitted on the substrate 1 and reflected by the substrate 1 is not emitted on the second YAG phosphor 2, is likely added to the illumination light E2, and is emitted.

In contrast, as illustrated in FIG. 3(b), since the light-emitting part 10b uses only the first YAG phosphor 3 having a relatively small particle size, the absorption index (that is, luminous efficiency) of the excitation light E1 is lower than that of the light-emitting part 10a. Accordingly, to compensate for the decrease in absorption index, it is required to increase the amount of the first YAG phosphor 3. Consequently, as illustrated in FIG. 3(b), the film thickness of the first phosphor layer La1 is increased. Since the film thickness is increased, heat release effect is decreased.

In contrast, since the light-emitting part 10b uses the first YAG phosphor 3 having a relatively small particle size, the excitation light E1 and the illumination light E2 can be efficiently scattered at the surface of the first YAG phosphor 3 when the excitation light E1 is incident and the illumination light E2 is emitted, as compared with the light-emitting part 10a. Accordingly, occurrence of color unevenness can be efficiently reduced in the illumination light E2. Also, it is not required to decrease the density of the first YAG phosphor 3 contained in the first phosphor-layer La1 in order to obtain a desirable color for the illumination light E2.

In the light-emitting part 10 according to this embodiment illustrated in FIG. 3(c), the first phosphor layer La1 containing the first YAG phosphor 3 having a relatively small particle size is arranged on the side far from the substrate 1, as described above. The excitation light E1 is incident on the first phosphor layer La1.

Since the first YAG phosphor 3 having a relatively small particle size is arranged on the side which is irradiated with the excitation light E1 first, the excitation light E1 can be efficiently scattered like the light-emitting part 10b. Also, the excitation light E1 can be efficiently scattered when the illumination light E2 is emitted like the light-emitting part 10b. Further, since the excitation light E1 can be efficiently scattered, the excitation light E1 and the yellow fluorescence are likely mixed. Accordingly, occurrence of color unevenness can be efficiently reduced in the illumination light E2.

If the first YAG phosphor 3 having a relatively small particle size is used, luminous efficiency with respect to the excitation light E1 is decreased as described above. However, in the light-emitting part 10, the second phosphor layer La2 containing the second YAG phosphor 2 having a relatively large particle size is arranged on the side near the substrate 1. Hence, even when the first YAG phosphor 3 having a relatively small particle size is used, the luminous efficiency can be prevented from being decreased. Also, by arranging the second phosphor layer La2, the film thickness of the light-emitting part 10 can be decreased. Hence, since the distance to the uppermost surface of the light-emitting part 10 (that is, the emission surface of the illumination light E2, and the upper surface of the first phosphor layer La1) is decreased, heat release effect can be increased.

Also, even when the second YAG phosphor 2 having a relatively large particle size is used, since the first YAG phosphor 3 having a relatively small particle size is stacked, an exposed portion is not present in the surface of the substrate 1. Hence, the excitation light E1 reflected by the substrate 1 is not directly emitted to the outside, and safety can be increased.

(Difference from PTL 1)

The semiconductor light-emitting device in PTL 1 includes a so-called transmissive-type light-emitting part (resin layer) (“transmissive-type” light-emitting part will be described in Embodiment 5). If the light-emitting part is used for a so-called reflective-type light-emitting part, excitation light passes through a scattering material (light scattering layer) contained in a resin layer before the excitation light is incident on a phosphor. Hence, light-beams of illumination light may be decreased due to multiple scattering, and the excitation light not absorbed by the phosphor and reflected by the phosphor may be increased. Also, when a phosphor having a relatively small particle size is dispersed in the resin layer, since the phosphor is separated from a light-emitting element (that is, element substrate), the temperature of the resin layer rises. As a result, the resin layer may be deteriorated, and luminous efficiency may be decreased.

In contrast, in the light-emitting part 10 according to this embodiment, the excitation light E1 is incident on the first YAG phosphor 3 having a relatively small particle size, and the illumination light E2 is emitted from the first YAG phosphor 3. Accordingly, occurrence; of color unevenness can be efficiently reduced without the scattering material. Since the scattering material is not provided, the decrease in light beams and the occurrence of reflected excitation light as described above can be reduced. Also, since the scattering material is not provided, the first YAG phosphor 3 and the second YAG phosphor 2 can efficiently absorb the excitation light E1.

Further, since the first YAG phosphor 3 and the second YAG phosphor 2 are stacked on the substrate (not dispersed in the resin layer), the neat generated from the first YAG phosphor 3 and the second YAG phosphor 2 can be efficiently released. Hence, occurrence of the deterioration in the light-emitting part 10 and the decrease in luminous efficiency as described above can be reduced.

### Example

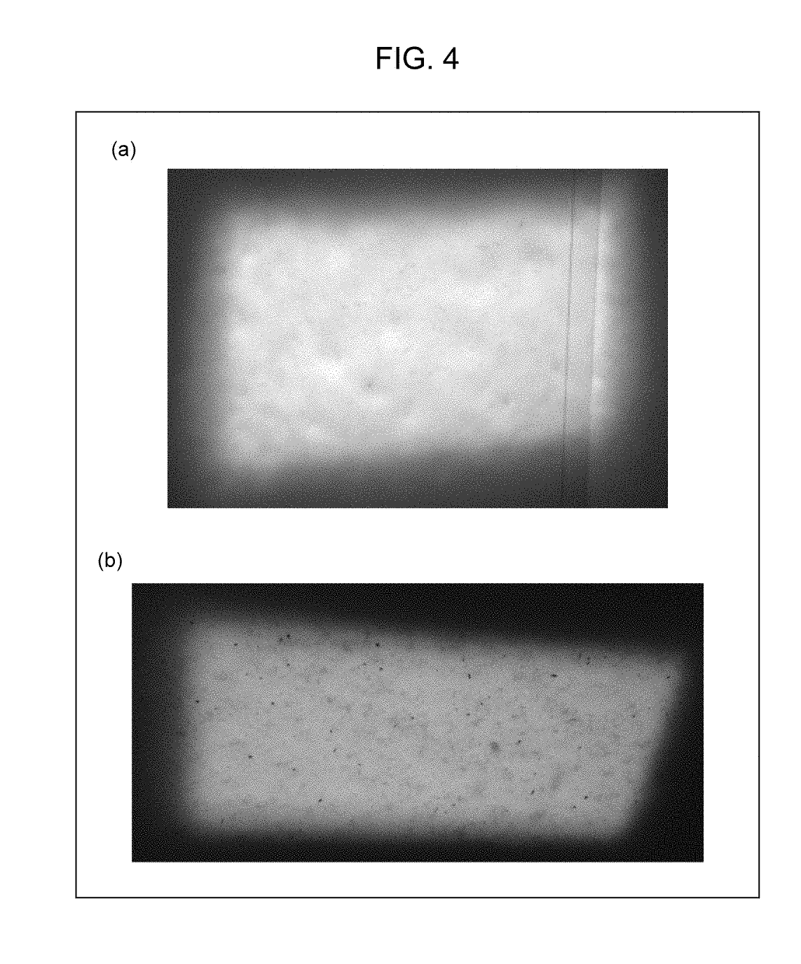

FIG. 4 provides illustrations for explaining a difference in projection pattern of illumination light E2 due to a difference in particle size of phosphors stacked on a substrate 1. FIG. 4(a) illustrates an experimental result of a light-emitting part 10 according to this example. FIG. 4(b) illustrates an experimental result of a light-emitting part 10a according to a comparative example.

In FIG. 4, a laser element 11 that emits excitation light E1 having a peak wavelength of 445 nm was used as an excitation light source. A first YAG phosphor 3 having a particle size (d50) of 9 μm was used. A second YAG phosphor 2 having a particle size (d50) of 13 μm was used. Illumination light E2 emitted from the light-emitting part 10 and the light-emitting part 10a were projected on a white wall surface from a projecting lens 17. The projection patterns formed by the illumination light E2 projected on the wall surface were captured. FIG. 4(a) illustrates the result of capturing the projection pattern formed by the illumination light E2 emitted from, the light-emitting part 10. FIG. 4(b) illustrates the result of capturing the projection pattern formed by the illumination light E2 emitted from the light-emitting part 10a.

Comparing FIG. 4(a) with FIG. 4(b), in FIG. 4(b), a near field, pattern of a phosphor layer of the light-emitting part 10b substantially directly appears, in which phosphor particles are yellow, gaps between the phosphor particles are blue, and the yellow color and the blue color are separated from one another. In contrast, in FIG. 4(a), gaps between phosphor particles are almost not present, the yellow color and the blue color are mixed and appear white, and hence color unevenness is reduced by a certain degree that does not cause a problem in practical use. That is, the color unevenness of the projection pattern (FIG. 4(a)) obtained from the light-emitting part 10 according to this example is more reduced, compared with the color unevenness of the projection pattern (FIG. 4(b)) obtained from the light-emitting part 10a according to the comparative example.

### Embodiment 2

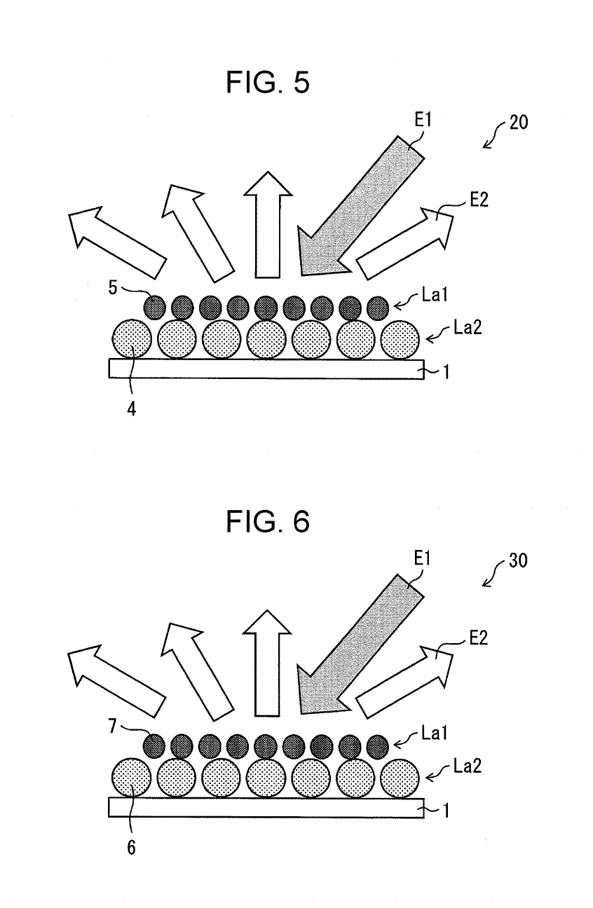

Another embodiment of the present invention is described as follows with reference to FIG. 5. For the convenience of description, the same reference sign is applied to a member having the same function as that of the member described in the aforementioned embodiment, and the description thereof is omitted.

FIG. 5 illustrates an outline configuration of a light-emitting part 20 (light-emitting body) according to this embodiment. The light-emitting part 20 of reflective type uses a green luminescent phosphor 5 as a first phosphor-contained in a first phosphor layer La1, and uses a red luminescent phosphor 4 as a second phosphor contained in a second phosphor layer La2. The light-emitting part 20 differs from, the light-emitting part 10 according to Embodiment 1 for this point. That is, the light-emitting part 20 according to this embodiment has a structure in which a first phosphor and a second phosphor of two kinds (i.e., different kinds) having mutually different emission wavelengths are stacked.

As illustrated in FIG. 5, the green luminescent phosphor 5 having a relatively small particle size and contained in the first phosphor layer La1 arranged on the incidence side of excitation light E1 (that is, the emission side of illumination light E2, and the side far from the substrate 1) emits, for example, green fluorescence (first-fluorescence) with a peak wavelength (emission peak wavelength) of about 530 nm. For the green luminescent phosphor 5, for example, a β-SiAlON phosphor may be used.

Also, the red luminescent phosphor 4 having a relatively large particle size and contained in the second phosphor layer La2 arranged on the side near the substrate 1 emits, for example, red fluorescence (second fluorescence) with a peak wavelength of about 630 nm. For the red luminescent phosphor 4, for example, a CaAlSiN₃:Eu phosphor (CASN phosphor), or (Sr, Ca) AlSiN₃:Eu phosphor (SCASN phosphor) may be used.

In this embodiment, the light-emitting part 20 emits illumination light E2 serving as white light in which blue light serving as excitation light E1, green fluorescence emitted from the green luminescent phosphor 5, and red fluorescence emitted from the red luminescent phosphor 4 are mixed.

Also, in this embodiment, the peak wavelength of the red luminescent phosphor 4 contained in the second phosphor layer La2 arranged on the side near the substrate 1 is longer than the peak wavelength of the green luminescent phosphor 5 contained in the first phosphor layer La1 arranged on the incidence side of the excitation light E1. The fluorescence from the second phosphor layer La2 is incident on the first phosphor layer La1. However, if a phosphor with a peak wavelength longer than that of the phosphor contained in the second phosphor layer La2 is contained in the first phosphor layer La1, the fluorescence from the second phosphor layer La2 may excite again the phosphor contained in the first phosphor layer La1. Hence, by arranging the green luminescent phosphor 5 having a short wavelength in the first phosphor layer La1, and arranging the red luminescent phosphor 4 having a long wavelength in the second phosphor layer La2, fluorescence from the second phosphor layer La2 can be prevented from, being absorbed again by the first phosphor layer La1.

However, if this point is not considered, the red luminescent phosphor 4 having a relatively small particle size may be contained in the first phosphor layer La1, and the green luminescent phosphor 5 having a relatively large particle size may be contained in the second phosphor layer La2. Also, the first phosphor and the second phosphor having the mutually different peak wavelengths are not limited to the red luminescent phosphor 4 and the green luminescent phosphor 5. A phosphor that emits other light may be appropriately selected in accordance with the oscillation wavelength range of the excitation light E1.

### <Advantageous Effects of Light-Emitting Part 20>

In the light-emitting part 20, the green luminescent phosphor 5 having a relatively small particle size is arranged on the incidence side of the excitation light E1 (the emission side of the illumination light E2), and hence occurrence of color unevenness and luminance unevenness can be efficiently reduced like Embodiment 1.

Since the green luminescent phosphor 5 and the red luminescent phosphor 4 are phosphors of mutually different kinds, the variety of colors of the illumination light E2 can be increased. For example, a red component may be added to white light serving as the illumination light E2. In this case, color rendering properties of the illumination light E2 can be improved.

Also, since the kinds of the phosphors are mutually different, even if the illumination light E2 does not include the excitation light E1, the light-emitting part 20 can emit illumination light E2 with a color similar to the color in the case where the illumination light E2 includes the excitation light E1. For example, the blue luminescent phosphor, the green luminescent phosphor, and the red luminescent phosphor are contained in either of the first phosphor and the second phosphor. Then the phosphors are irradiated with excitation light E1 of 405 nm. Thus, white light (illumination light E2) can be generated only with the fluorescence.

### Embodiment 3

Still another embodiment of the present invention is described as follows with reference to FIG. 6. For the convenience of description, the same reference sign is applied to a member having the same function as that of the member described in the aforementioned embodiment, and the description thereof is omitted.

FIG. 6 illustrates an outline configuration of a light-emitting part 30 (light-emitting body) according to this embodiment. The light-emitting part 30 of reflective type uses a green luminescent phosphor 7 as a first phosphor contained in a first phosphor layer La1, and uses a red luminescent phosphor 6 as a second phosphor contained in a second phosphor layer La2. The light-emitting part 30 differs from, the light-emitting part 10 according to Embodiment 1 for this point. That is, the light-emitting part 30 according to this embodiment has a structure in which the first phosphor and the second phosphor of the two kinds (i.e., different kinds) having mutually different emission wavelengths are stacked.

As illustrated in FIG. 6, the green luminescent phosphor 7 having a relatively small particle size and contained in the first phosphor layer La1 arranged on the incidence side of excitation light E1 (that is, the emission side of illumination light E2, and the side far from the substrate 1) emits, for example, green fluorescence (first fluorescence) with a peak wavelength (emission peak wavelength) of about 530 nm. For the green luminescent-phosphor 7, for example, a β-SiAlON phosphor like Embodiment 2 may be used. Also, the green luminescent phosphor 7 has smaller thermal quenching than that of the red luminescent phosphor 6.

Also, the red luminescent phosphor 6 having a relatively large particle size and contained in the second phosphor layer La2 arranged on the side near the substrate 1 with respect to the first phosphor layer La1 emits, for example, red fluorescence (second fluorescence) with a peak wavelength of about 630 nm. For the red luminescent phosphor 6, for example, a CASN phosphor or a SCASN phosphor like Embodiment 2 may be used. Also, the red luminescent phosphor 6 has larger thermal quenching than that of the green luminescent phosphor 7.

That is, in the light-emitting part 30, the green luminescent phosphor 7 having a relatively small particle size and having relatively small thermal quenching is arranged on the incidence side of the excitation light E1, and the red luminescent phosphor 6 having a relatively large particle size and having relatively large thermal quenching is arranged on the side near the substrate 1.

The thermal quenching represents that the luminous efficiency of a phosphor decreases as the temperature rises. The state in which the thermal quenching is large (or small) represents that the degree of decrease in luminous efficiency of a phosphor with respect to the rate of temperature rise is large (or small).

The light-emitting part 30 emits illumination light E2 serving as white light in which blue light serving as excitation light E1, green fluorescence emitted from the green luminescent phosphor 7, and red fluorescence emitted from, the red luminescent phosphor 6 are mixed.

The first phosphor and the second phosphor having the mutually different peak, wavelengths are not limited to the red luminescent phosphor 6 and the green luminescent phosphor 7. That is, a phosphor having relatively small thermal quenching may be selected as the first phosphor, and a phosphor having relatively large thermal quenching may be selected as the second, phosphor. Also, for the first phosphor and the second phosphor, a phosphor that emits other light may be appropriately selected in accordance with the oscillation wavelength range of the excitation light E1.

### <Advantageous Effects of Light-Emitting Part 30>

The configuration in which the first phosphor and the second phosphor of the mutually different kinds are stacked is similar to the configuration of Embodiment 2; however, this embodiment focuses on the difference in degree of the thermal quenching depending on the kind.

For example, it is known that a silicate-based phosphor exhibits a large decrease in luminous efficiency with respect to the rate of temperature rise, and a SiAlON phosphor or a YAG phosphor exhibits a small decrease in luminous efficiency with respect to the rate of temperature rise.

The heat generated from the reel luminescent phosphor 6 and the heat generated from the green luminescent phosphor 7 are released via the substrate 1. Hence, in the light-emitting part 30, the temperature is lower as the position is closer to the substrate 1, and the temperature is higher as the position is farther from the substrate 1. Hence, in this embodiment, the reel luminescent phosphor 6 having large thermal quenching is deposited on the side near the substrate 1 the temperature of which less likely rises, and the green luminescent phosphor 7 having small thermal quenching is deposited thereon. In other words, the red luminescent phosphor 6 containing a CASN phosphor or a SCASN phosphor having relatively large thermal quenching is arranged at a position closer to the substrate 1 as compared with the green luminescent phosphor 7 containing a β-SiAlON phosphor having relatively small thermal quenching. Hence, the temperature rise of the red luminescent phosphor 6 having a greater degree of decrease in luminous efficiency along with the temperature rise can be reduced with higher priority. Accordingly, the decrease in luminous efficiency of the light-emitting part 30 during excitation by the excitation light E1 (in particular, strong excitation) can be reduced.

Further, in the light-emitting part 30, the green luminescent phosphor 7 having a relatively small particle size is arranged on the incidence side of the excitation light E1 (the emission side of illumination light E2), and hence occurrence of color unevenness and luminance unevenness can be efficiently reduced like Embodiment 1.

### Embodiment 4

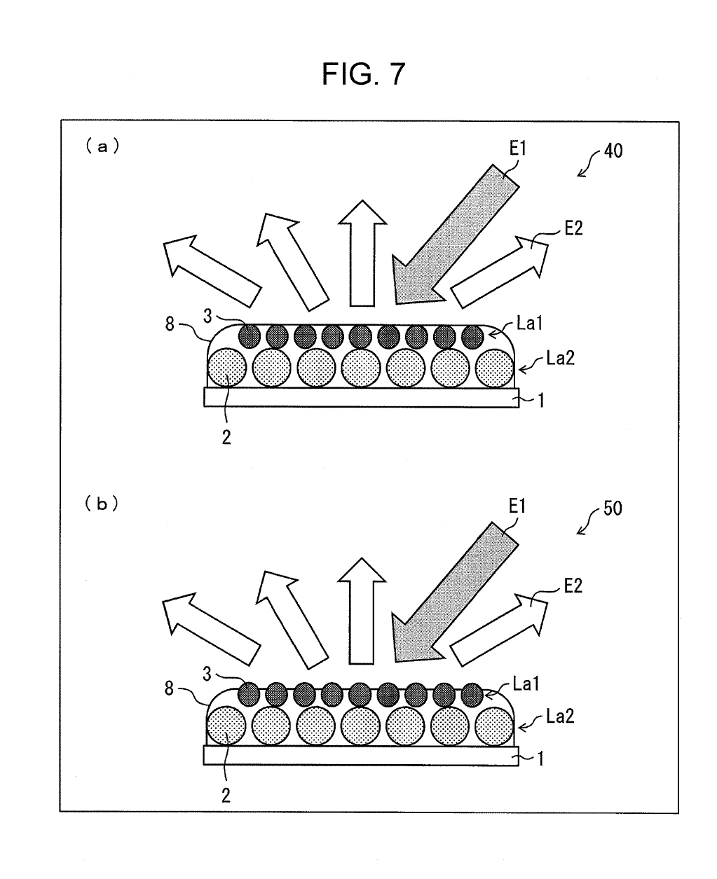

Yet another embodiment of the present invention is described as follows with reference to FIG. 7. For the convenience of description, the same reference sign is applied to a member having the same function as that of the member described in the aforementioned embodiment, and the description thereof is omitted.

FIG. 7(a) illustrates an outline configuration of a light-emitting part 40 (light-emitting body) according to this embodiment. FIG. 7(b) illustrates an outline configuration of a light-emitting part 50 (light-emitting body) according to this embodiment.

As illustrated in FIG. 7(a) and FIG. 7(b), the reflective-type light-emitting parts 40 and 50 each have a configuration in which a first phosphor layer La1 and a second phosphor layer La2 are entirely or partly covered with a sealing material 8.

Specifically, as illustrated in FIG. 7(a), the light-emitting part 40 has a configuration in which a first YAG phosphor 3 serving as a first phosphor, and a second YAG phosphor 2 serving as a second phosphor are completely covered with the sealing material 8. In contrast, as illustrated in FIG. 7(b), the light-emitting part 50 has a configuration in which a first YAG phosphor 3 and a second YAG phosphor 2 are covered with the sealing material 8 so that a portion of the surface of the first YAG phosphor 3 is exposed. More specifically, in the light-emitting part 50, an upper surface of the first phosphor layer La1 (a surface on which excitation light E1 is incident) is not sealed with the sealing material 8 and is exposed. The surface has protrusions and depressions due to the first YAG phosphor 3 covered with a binding material.

In other words, the sealing material 8 entirely or partly seals the first phosphor layer La1 and the second phosphor layer La2, and hence fills a gap between particles of the first YAG phosphor 3 serving as the first phosphor, a gap between particles of the second YAG phosphor 2 serving as the second phosphor, and a gap between the first YAG phosphor 3 and the second YAG phosphor 2. The sealing material 8 is preferably an inorganic compound having high heat resistance and high thermal conductivity, and may be, for example, silica such as SiO₂, or TiO₂. Alternatively, resin or the like may be employed as the sealing material 8.

The major configuration of each of the light-emitting parts 40 and 50 other than the sealing material 8 is similar to the configuration of the light-emitting part 10 according to Embodiment 1 illustrated in FIG. 2. Also, the sealing material 8 may be used for the light-emitting part 20 according to Embodiment 2, and the light-emitting part 30 according to Embodiment 3.

### <Advantageous Effects of Light-Emitting Parts 40 and 50>

In each of the light-emitting parts 40 and 50, the first YAG phosphor 3 having a relatively small particle size is arranged on the incidence side of the excitation light E1 (the emission side of illumination light E2), and hence occurrence of color unevenness and luminance unevenness can be efficiently reduced like Embodiment 1.

Also, in each of the light-emitting parts 40 and 50, the first phosphor layer La1 and the second phosphor layer La2 are entirely or partly sealed with the sealing material 8 to fill the aforementioned gaps. Hence, the thermal conductivity of the entirety of the light-emitting parts 40 and 50 can be increased. Accordingly, the heat generated from, the light-emitting parts 40 and 50 can be further efficiently released.

Also, as illustrated in FIG. 7(b), in the light-emitting part 50, the upper surface of the first phosphor layer La1 is exposed, and the protrusions and depressions are formed at the surface. Hence, the difference in refractive index with respect to the air can be increased at the surface, and the excitation light E1 can be likely diffused and reflected by the projections and depressions at the surface. Hence, as compared with the light-emitting part 40 in which the upper surface of the first phosphor layer La1 is completely sealed with the sealing material 8 illustrated in FIG. 7(a), the excitation light E1 and the illumination light E2 can be further efficiently scattered. Consequently, since the excitation light E1 is likely mixed with fluorescence, occurrence of color unevenness can be reduced in the illumination light E2. Similar advantageous effects can be attained in any of the light-emitting parts 10 to 30 according to Embodiments 1 to 3.

### Embodiment 5

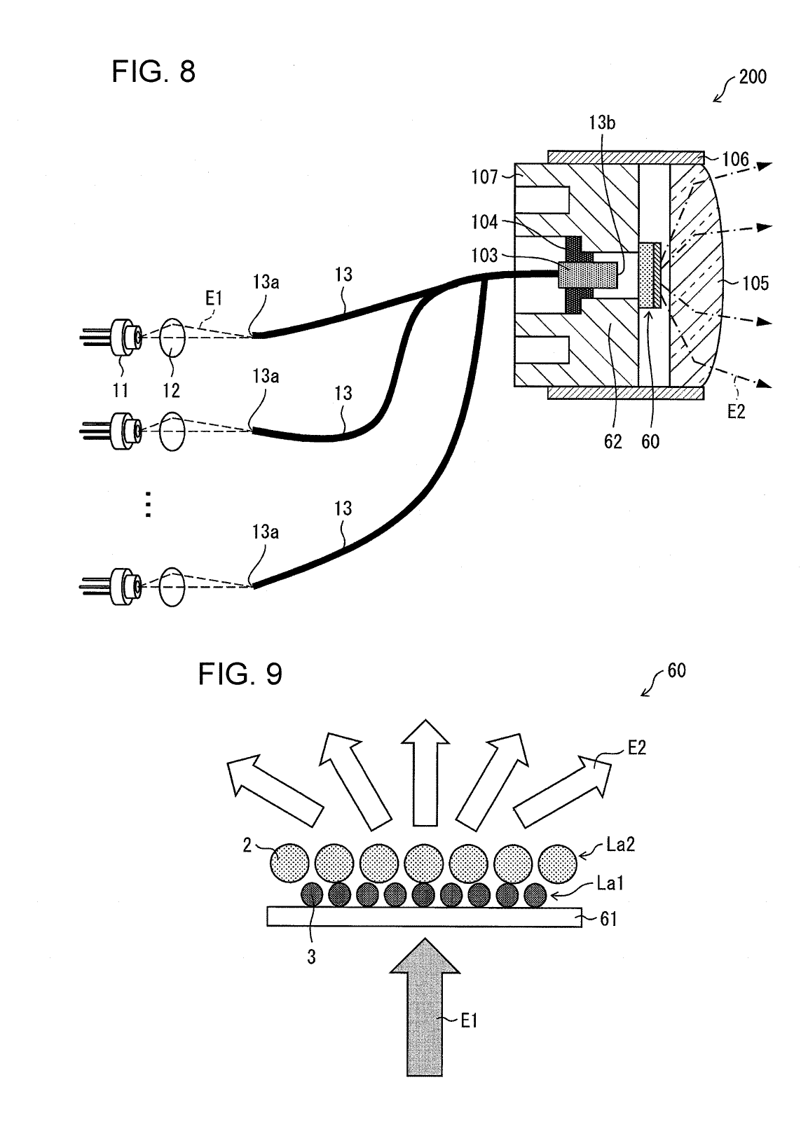

A further embodiment of the present invention is described as follows with reference to FIGS. 8 and 9. For the convenience of description, the same reference sign is applied to a member having the same function as that of the member described in the aforementioned embodiment, and the description thereof is omitted. Unlike Embodiments 1 to 4, in this embodiment, an illuminator 200 including a transmissive-type light-emitting part 60 (light-emitting body) is described.

### <Outline Configuration of Illuminator 200>

FIG. 8 illustrates an outline configuration of the illuminator 200 according to this embodiment. As illustrated in FIG. 8, the illuminator 200 includes a laser element 11, a first lens 12, an optical fiber 13, the light-emitting part 60, a fixing jig 62, a ferrule 103, a ferrule fixing part 104, a projecting lens 105 (projecting part), a lens fixing part 106, and a heat release fin 107. The light-emitting part 60 and the laser element 11 form a basic configuration of a light-emitting device. Also, the light-emitting part 60, the laser element 11, and the projecting lens 105 form a basic configuration of an illuminator.

The illuminator 200 projects illumination light E2 including at least fluorescence that is emitted from the light-emitting part 60 when excited by excitation light E1 emitted from the laser element 11, in a specific direction by the projecting lens 105. While this embodiment is described such that the illumination light E2 includes the excitation light E1 and the fluorescence, only the fluorescence may be projected as the illumination light E2.

Also, in this embodiment, the illuminator 200 includes a plurality of laser elements 11. The number of laser elements 11 can be appropriately changed depending on the required output. The first lens 12 is arranged to face corresponding one of the laser elements 11. The optical fiber 13 has a certain number of incidence ends 13a on which the excitation light E1 is incident and the number of which corresponds to the number of the laser elements 11, and a single emission end 13b from which the excitation light E1 is emitted to the light-emitting part 60. The optical fiber 13 may be a fiber bundle in which a certain number of optical fibers corresponding to the number of laser elements 11 are bundled.

The fixing jig 62 is a member to which the light-emitting part 60 is fixed. The fixing jig 62 has a cylindrical shape. The light-emitting part 60 is thermally bonded to one end of the cylindrical fixing jig 62 by using silicon grease.

A specific example of the material constituting the fixing jig 62 may be metal, such as aluminum, copper, iron, or silver. The surface of aluminum may be black anodized. In this embodiment, black anodized aluminum is used as the material of the fixing jig 62.

The ferrule 103 holds the optical fiber 13. Specifically, the ferrule 103 holds the periphery of the optical fiber 13 at a position near the emission end 13b.

The ferrule fixing part 104 is a member for fixing the ferrule 103 to the illuminator 200. The ferrule fixing part 104 is provided at an end portion of the fixing jig 62 on a side opposite to one end to which the light-emitting part 60 is fixed. Since the ferrule 103 is fixed to the ferrule fixing part 104, the emission end 13b of the optical fiber 13 held by the ferrule 103 is fixed at a position facing the light-emitting part 60.

The projecting lens 105 is a projecting member (projection optical system) that projects the illumination light E2 including at least the fluorescence emitted from the light-emitting part 60 to the outside, like the projecting lens 17.

The lens fixing part 106 is a member that fixes the relative positions of the light-emitting part 60 and the projecting lens 105. The lens fixing part 106 is a cylindrical member surrounding the peripheries of the fixing jig 62 and the projecting lens 105. The material of the lens fixing part 106 is preferably one having high heat release effect. For example, anodized aluminum may be suitably used as the material of the lens fixing part 106.

The heat release fin 107 is a member that increases heat release efficiency of the fixing jig 62. The heat release fin 107 is provided on the side of the fixing jig 62 on which the ferrule fixing part 104 is provided. The shape, size, and number of the heat release fin 107 are determined depending on the output of the laser element 11 and the specifications of the light-emitting part 60. Hence, the neat release performance of the fixing jig 62 can be increased. Accordingly, the decrease in luminous efficiency of the light-emitting part 60 along with the temperature rise can be reduced.

### <Specific Configuration of Light-emitting Part 60>

Next, a specific configuration of the light-emitting part 60 is described with reference to FIG. 9. FIG. 9 illustrates an outline configuration of the light-emitting part 60 of transmissive type. As illustrated in FIG. 9, the light-emitting part 60 includes a transmissive substrate 61 (substrate), and a phosphor film including a first phosphor layer La1 and a second phosphor layer La2.

The first phosphor layer La1 is a layer containing a particulate first phosphor that receives excitation light E1 and emits first fluorescence. The second phosphor layer La2 is a layer containing a particulate second phosphor that receives the excitation light E1 and emits second fluorescence. The first phosphor layer La1 and the second phosphor layer La2 are stacked on the substrate 1. That is, the light-emitting part 60 has a double-layer structure.

As illustrated in FIG. 9, in the light-emitting part 60, the first phosphor layer La1 and the second phosphor layer La2 are stacked on the transmissive substrate 1 in that order from the incidence side of the excitation light E1. That is, in the light-emitting part 60, the first phosphor layer La1 is arranged on a side near the transmissive substrate 61, and the excitation light E1 is incident on a surface of the first phosphor layer La1 facing the transmissive substrate 61 (that is, a surface of the first phosphor layer La1 on a side opposite to a surface thereof facing the second phosphor layer La2) via the transmissive substrate 61. Illumination light E2 including the first fluorescence and the second fluorescence is emitted from a surface of the second phosphor layer La2 arranged on a side far from the substrate 1 opposite to a surface thereof facing the first phosphor layer La1 (an upper surface of the second phosphor layer La2). That is, in the light-emitting part 60, the surface on which, the excitation light E1 is mainly incident and the surface from which the fluorescence is mainly emitted to the outside are opposite to one another. In this application, such, a light-emitting part is called a “transmissive-type” light-emitting part.

In this embodiment, the first phosphor is a first YAG phosphor 3, and the second phosphor is a second YAG phosphor 2, In this embodiment, by irradiating the light-emitting part 60 with excitation light E1 of 450 nm (blue) (or excitation light E1 of near blue), white light (so-called quasi white light) serving as the illumination light E2 can be obtained.

As described in Embodiment 1, the first phosphor and the second phosphor may be of mutually different kinds, only fluorescence may be emitted as the illumination light E2, and light other than white light may be emitted as the illumination light E2. That is, the oscillation wavelength range of the laser element 11, and the kinds of the first phosphor and the second phosphor are appropriately selected so that the illumination light E2 of a color that is required for a light-emitting device can be emitted.

Also, like Embodiment 1, particles of the first YAG phosphor 3 are preferably bound to one another, particles of the second YAG phosphor 2 are preferably bound to one another, and the second YAG phosphor 2 and the transmissive substrate 61 are preferably bound to one another by a binding material (binder).

Also, In this embodiment, as illustrated in FIG. 9, the particle size of the first YAG phosphor 3 arranged on the incidence side of the excitation light E1 is smaller than the particle size of the second YAG phosphor 2 arranged on the side far from the transmissive substrate 61. That is, unlike Embodiment 1, only the first YAG phosphor 3 having a relatively small particle size is arranged on the side near the transmissive substrate 61.

The transmissive substrate 61 supports the first phosphor layer La1 and the second phosphor layer La2. The first phosphor layer La1 and the second phosphor layer La2 are formed on a surface of the transmissive substrate 61 on the side opposite to the surface thereof on which the excitation light E1 is incident. For the material of the transmissive substrate 61, for example, glass or sapphire may be used. The size of the transmissive substrate 61 when viewed from the incidence side of the excitation light E1 is equal to the size of the first phosphor layer La1 and the second phosphor layer La2, or larger than the size of the first phosphor layer La1 and the second phosphor layer La2.

In the light-emitting part 60 according to this embodiment, the blue light serving as the excitation light E1 is transmitted through the transmissive substrate 61 and then is emitted on the first phosphor layer La1 containing the first YAG phosphor 3 having a relatively small particle size. In the first phosphor layer La1, the first YAG phosphor 3 absorbs the excitation light E1, and emits yellow fluorescence serving as the first fluorescence. Then, in the second phosphor layer La2 containing the second YAG phosphor 2 having a relatively large particle size, the second YAG phosphor 2 absorbs the excitation light E1 not absorbed by the first YAG phosphor 3, and emits yellow fluorescence serving as the second fluorescence. (1) The excitation light E1 not absorbed by the first YAG phosphor 3 and the second YAG phosphor 2, and (2) the yellow fluorescence serving as the first fluorescence and the second fluorescence are mixed, and the illumination light E2 serving as quasi white light is emitted from, the second phosphor layer La2.

Also, in the light-emitting part 60, a dielectric, multilayer film that transmits the excitation light E1 and reflects the fluorescence may be formed between the phosphor film including the first phosphor layer La1 and the second phosphor layer La2, and the transmissive substrate 61. For the transmissive substrate 61, sapphire having high thermal conductivity is suitable to release the heat generated from the phosphor film. Also, it is desirable that the transmissive substrate 61 contacts the heat sink.

The fluorescence generated from the phosphor film is emitted in all directions from, the second phosphor layer La2. However, if the dielectric multilayer film is formed, the fluorescence emitted, in a direction, toward the ferrule 103 is reflected in a direction toward the projecting lens 105. Accordingly, light extraction efficiency from the light-emitting part 60 is increased, and the illuminator 200 having higher luminance can be provided.

Also, in the light-emitting part 60, a surface of the transmissive substrate 61 on a side near the ferrule 103 may be provided with AR (Anti-Reflection) coating. In this case, the reflectivity of the excitation light E1 at the surface of the transmissive substrate 61 is decreased, and the ratio of the excitation, light E1 to be incident on the phosphor film, is increased. Accordingly, the light extraction efficiency from the light-emitting part 60 is increased, and the illuminator 200 having higher luminance can be provided.

### <Method for Producing Light-Emitting Part 60>

Next, a method for producing the light-emitting part 60 is described. The light-emitting part 60 is produced by, for example, sedimentation.

In sedimentation, for example, the first YAG phosphor 3 having a relatively small particle size is dispersed in slurry. Then, the transmissive substrate 61 is dipped in the slurry in which the first YAG phosphor 3 is dispersed, and hence the first YAG phosphor 3 is deposited on the transmissive substrate 61. Then, the transmissive substrate 61 on which the first YAG phosphor 3 is deposited is taken out from the slurry, and dried.

Then, the second YAG phosphor 2 having a relatively large particle size is dispersed in slurry. Then, the transmissive substrate 61 on which the first YAG phosphor 3 is deposited is dipped in the slurry in which the second YAG phosphor 2 is dispersed, and hence the second YAG phosphor 2 is deposited on the first YAG phosphor 3. Then, the transmissive substrate 61 on which the first YAG phosphor 3 and the second YAG phosphor 2 are deposited is taken out from the slurry, and dried.

The first YAG phosphor 3 and the second YAG phosphor 2 are coated with a binding material. The first YAG phosphor 3 and the second YAG phosphor 2 may be collectively coated after being dried, or may be coated as follows. That is, after the first phosphor layer La1 (first phosphor layer) is formed, the first YAG phosphor 3 is coated with the binding material. Then, after the second phosphor layer La2 (second phosphor layer) is formed, the second YAG phosphor 2 is coated with the binding material.

Also, the method for producing the light-emitting part 60 may be provided by screen printing, application using a dispenser, electrophoresis, or another method, without limiting to the sedimentation. The method for producing the light-emitting part 60 using these methods is substantially similar to the content described in Embodiment 1 except for the following points. That is, in this embodiment, the first phosphor layer La1 containing the first YAG phosphor 3 is formed on the transmissive substrate 61, and then the second phosphor layer La2 containing the second YAG phosphor 2 is formed on the first phosphor layer La1.

### <Advantageous Effects of Light-Emitting Part 60>

In the light-emitting part 60 according to this embodiment, the excitation light E1 is emitted on the first YAG phosphor 3 contained in the first phosphor layer La1 and having a relatively small particle size. Hence, since the excitation light E1 can be efficiently scattered, the excitation light E1 and the yellow fluorescence are likely mixed. Accordingly, occurrence of color unevenness can be efficiently reduced in the illumination light E2 that is emitted from the light-emitting part 60. Also, if the kinds of the first phosphor and the second phosphor constituting the light-emitting part 60 are the same kind and only the fluorescence excited by the excitation light E1 is emitted from the light-emitting part 60, occurrence of luminance unevenness can be efficiently reduced in the illumination light E2 emitted from the light-emitting part 60 and containing only the fluorescence.

Also, like Embodiment 1, the light-emitting part 60 includes the second phosphor layer La2 containing the second YAG phosphor 2 having a relatively large particle size. Hence, the decrease in luminous efficiency which may be generated when the first YAG phosphor 3 having a relatively small particle size is used can be prevented. Also, by arranging the second phosphor layer La2, as compared with a case where only the first phosphor layer La1 is stacked on the transmissive substrate 61, the film thickness of the light-emitting part 60 can be decreased. Hence, since the distance to the uppermost surface of the light-emitting part 60 (that is, the emission surface of the illumination light E2, and the upper surface of the second phosphor layer La2) is decreased, heat release effect can be increased.

Also, when only the second YAG phosphor 2 having a relatively large particle size is used for the light-emitting part, as described in Embodiment 1, the gap between the particles of the second YAG phosphor 2 is increased. The surface of the transmissive substrate 61 is exposed, and the surface may be viewed from the emission side of the illumination light E2. In this case, the excitation light E1 emitted from the exposed potion may not be emitted on the second YAG phosphor 2, and may be directly emitted to the outside of the light-emitting part. In this embodiment, the first YAG phosphor 3 having a relatively small particle size, together with the second YAG phosphor 2, is stacked on the transmissive substrate 61. Hence, the excitation light E1 emitted from the exposed portion is emitted on the first YAG phosphor 3 before the excitation light E1 is transmitted through the gap. Accordingly, the excitation light E1 is not directly emitted to the outside, and safety can be increased.

In general, a phosphor having a relatively small particle size more likely generates heat due to lower internal quantum efficiency as compared with a phosphor having a relatively large particle size. Hence, if the phosphor having a relatively small particle size is arranged on the incidence side of the excitation light, the light-emitting part entirely more likely generates heat.

In this embodiment, while the first phosphor layer La1 containing the first YAG phosphor 3 having a relatively small particle size is provided on the incidence side of excitation light E1, the first phosphor layer La1 is arranged on the transmissive substrate 61. Hence, the heat generated from the first phosphor layer La1 can be efficiently released to the transmissive substrate 61. Accordingly, even when the excitation light E1 is incident on the first phosphor layer La1, the heat generated from the light-emitting part 60 can be efficiently released.

### <Modification 1>

In the transmissive-type light-emitting part 60, the kind of the first phosphor and the kind of the second phosphor may differ from one another. That is, the peak wavelength (emission peak wavelength) of the first phosphor and the peak wavelength of the second phosphor may differ from one another. For example, a red luminescent phosphor that emits red fluorescence (first fluorescence) may be used as the first phosphor having a relatively small particle size, and a green luminescent phosphor that emits green fluorescence (second fluorescence) may be used as the second phosphor having a relatively large particle size.

In this case, the peak wavelength of the reel luminescent phosphor contained in the first phosphor layer La1 arranged on the side near the substrate 1 (that is, the incidence side of the excitation light E1) is longer than the peak wavelength of the green luminescent phosphor contained in the second phosphor layer La2 arranged on the first phosphor layer La1. In this case, the fluorescence from the first phosphor layer La1 excites again the phosphor of the second phosphor layer La2, and can prevent the luminous efficiency from being decreased.

Also, since the kind of the first phosphor differs from the kind of the second phosphor as described in Embodiment 2, the variety of colors of the illumination light E2 can be increased. Also, even if the illumination light E2 does not include the excitation light E1, the light-emitting part 60 can emit illumination light E2 with a color similar to the case where the illumination light E2 includes the excitation light E1.

However, if this point is not considered, the green luminescent phosphor having a relatively small particle size may be contained in the first phosphor layer La1, and the red luminescent phosphor having a relatively large particle size may be contained in the second phosphor layer La2. Also, the first phosphor and the second phosphor having the mutually different peak wavelengths are not limited to the red luminescent phosphor and the green luminescent phosphor. A phosphor that emits other light may be appropriately selected in accordance with the oscillation wavelength range of the excitation light E1.

### <Modification 2>

In the transmissive-type light-emitting part 60, the first phosphor having a relatively small particle size and relatively large thermal quenching may be arranged on the incidence side of the excitation light E1 (that is, on the side near the transmissive substrate 61), and the second phosphor having a relatively large particle size and relatively small thermal quenching may be arranged on the emission side of the illumination light E2. That is, the thermal quenching of the first phosphor arranged on the side near the transmissive substrate 61 is larger than the thermal quenching of the second phosphor. In this case, like Modification 1, the red luminescent phosphor may be used as the first phosphor, and the green luminescent phosphor may be used as the second phosphor.

Since the first phosphor having relatively large thermal quenching is arranged on the side near the transmissive substrate 61, the decrease in luminous efficiency of the light-emitting part 60 during excitation by the excitation light E1 (in particular, strong excitation) can be reduced like Embodiment 3.

The first phosphor and the second phosphor having the mutually different peak wavelengths are not limited to the red luminescent phosphor and the green luminescent phosphor. That is, a phosphor having relatively large thermal quenching may be selected as the first phosphor, and a phosphor having relatively small thermal quenching may be selected as the second phosphor. Also, for the first phosphor and the second phosphor, a phosphor that emits other light may be appropriately selected in accordance with the oscillation wavelength range of the excitation light E1.

### <Modification 3>

Like Embodiment 4, the transmissive-type light-emitting part 60 may be sealed with the sealing material 8. In this case, thermal conductivity can be increased for the entire light-emitting part 60.

### [Appendix]

A light-emitting body (light-emitting part 10, 20, 30, 40, 50) according to a first aspect of the invention includes
a first phosphor layer (La1) containing a first phosphor (first YAG phosphor 3, green luminescent phosphor 5, 7) that receives excitation light (E1) and emits first fluorescence; and
a second phosphor layer (La2) containing a second phosphor (second YAG phosphor 2, red luminescent phosphor 4, 6) that receives the excitation light and emits second fluorescence, in which
the first and second phosphor layers are stacked on a substrate (1),
a particle size of the first phosphor is smaller than a particle size of the second phosphor, and
the first phosphor layer is arranged on a side far from the substrate, and the excitation light is incident on the first phosphor layer,
With the above-described configuration, the first phosphor layer is arranged on the side far from the substrate, and the excitation light is incident on the first phosphor layer. In this case, when the first fluorescence; and the second fluorescence are emitted from the light-emitting body, the first fluorescence and the second fluorescence are emitted on the first phosphor contained in the first phosphor layer and having a relatively small particle size, the first fluorescence and the second fluorescence can be efficiently scattered. Accordingly, occurrence of luminance unevenness or color unevenness can be efficiently reduced in light that is emitted from the light-emitting body.

Furthermore, a light-emitting body (light-emitting part 60) according to a second aspect of the invention includes
a first phosphor layer (La1) containing a first phosphor (first YAG phosphor 3, red luminescent phosphor) that receives excitation light (E1) and emits first fluorescence; and
a second phosphor: layer (La2) containing a second phosphor (second YAG phosphor 2, green luminescent phosphor) that receives the excitation light and emits second fluorescence, in which
the first and second phosphor layers are stacked on a substrate (transmissive substrate 61),
a particle size of the first phosphor is smaller than a particle size of the second phosphor, and
the first phosphor layer is arranged on the substrate, and the excitation light is incident on the first phosphor layer.

In general, a phosphor having a relatively small particle size more likely generates heat due to lower internal quantum, efficiency as compared with a phosphor having a relatively large particle size. Hence, if the phosphor having a relatively small particle size is arranged on the incidence side of the excitation light, the light-emitting body entirely likely generates heat.

With the above-described configuration, the first phosphor layer is arranged on the substrate, and the excitation light is incident on the first phosphor layer. Hence, even if the first phosphor layer containing the first phosphor having a relatively small particle size is provided on the incidence side of the excitation light, since the first phosphor layer is arranged on the substrate, the heat generated from the first phosphor layer can be efficiently released. Accordingly, even when the excitation light is incident on the first phosphor layer, the heat generated from the light-emitting body can be efficiently released.

Preferably, in a light-emitting body according to a third aspect of the invention, based on the first or second aspect,
a kind of the first phosphor differs from a kind of the second phosphor.

With the above-described configuration, the variety of colors of the light that is emitted by the light-emitting body can be increased. Also, even if the light that is emitted by the light-emitting body does not include the excitation light, the light-emitting body can emit light with a color similar to the color in the case where the light includes the excitation light.

Preferably, in a light-emitting body according to a fourth aspect of the invention, based on the first aspect, an emission peak wavelength of the second phosphor is longer than an emission peak wavelength of the first phosphor.

With the above-described configuration, the first phosphor can be prevented from, being excited again by the fluorescence from the second phosphor.

Preferably, in a light-emitting body according to a fifth aspect of the invention, based on the second aspect,
an emission peak wavelength of the first phosphor is longer than an emission peak wavelength of the second phosphor.

With the above-described configuration, the second phosphor can be prevented from being excited again by the fluorescence from the first phosphor.

Preferably, in a light-emitting body according to a sixth aspect of the invention, based on the first aspect, the second phosphor layer is arranged on a side near the substrate with respect to the first phosphor layer, and thermal quenching of the second phosphor is larger than thermal quenching of the first phosphor.

In general, when excitation light is incident on a light-emitting body, the temperature of the light-emitting body on the incidence side of the excitation light is higher than the temperature on a side near a substrate.

With the above-described configuration, the second phosphor having larger thermal quenching than that of the first phosphor is arranged on the side near the substrate. Hence, thermal quenching less likely occurs in the second phosphor as compared with the first phosphor. Accordingly, the luminous efficiency of the light-emitting body can be prevented from, being decreased.

Preferably, in a light-emitting body according to a seventh aspect of the invention, based on the second aspect,
thermal quenching of the first phosphor is larger than thermal quenching of the second phosphor.

With the above-described configuration, the first phosphor having larger thermal quenching than that of the second phosphor is arranged on the side near the substrate. Hence, thermal quenching less likely occurs in the first phosphor as compared with the second phosphor. Accordingly, the luminous efficiency of the light-emitting body can be prevented from being decreased.

Furthermore, a light-emitting device according to an eighth aspect of the invention includes
an excitation light source (laser element 11) that emits the excitation light; and
the light-emitting body according to any one of the first to seventh aspects.

With the above-described configuration, like the first aspect, a light-emitting device capable of reducing occurrence of luminance unevenness or color unevenness in light to be emitted can be provided. Alternatively, like the second aspect, a light-emitting device capable of efficiently releasing the heat generated from a phosphor can be provided.

Preferably, in a light-emitting device according to a ninth aspect of the invention, based on the eighth aspect,
the excitation light source is a laser element (11).

With the above-described configuration, the luminous efficiency of the light-emitting body can be increased.

Further, an illuminator (100, 200) according to a tenth aspect of the invention includes
the light-emitting device according to the eighth or ninth aspect; and
a projecting part (projecting lens 17, 105) that projects the first fluorescence and the second fluorescence emitted from the light-emitting device.

With the above-described configuration, like the first aspect, an illuminator capable of reducing occurrence of luminance unevenness or color unevenness in light to be emitted can be provided. Alternatively, like the second aspect, an illuminator capable of efficiently releasing the heat generated from the phosphor can be provided.

Further, a producing method according to an eleventh aspect of the invention is
a method for producing the light-emitting body according to any one of the first to seventh aspects, the method including
stacking the first phosphor and the second phosphor on the substrate by electrophoresis or sedimentation.

With the above-described configuration, the light-emitting body according to the first or second aspect can be produced. Also, the density (concentration) of the first phosphor in the first phosphor layer, and the density (concentration) of the second phosphor in the second phosphor layer can be increased. Hence, a gap between particles of the first phosphor and a gap between particles of the second phosphor can be decreased, and consequently the layer thickness of each layer can be decreased. Accordingly, the thickness of the light-emitting body in a direction in which respective layers are stacked on the substrate can be decreased.

### [Other Expressions According to Aspect of the Invention]

Alternatively, an aspect of the invention can be expressed as follows.

That is, a light-emitting device according to an aspect of the invention includes a semiconductor light-emitting element that emits light; and a phosphor member containing a phosphor that converts the light from the semiconductor-light-emitting element into fluorescence of a color different from a color of the light from the semiconductor light-emitting element and provided on a substrate with a high reflectivity. The light-emitting device mixes the color of the light from the semiconductor light-emitting element and the color of the fluorescence from the phosphor-member and emits light, in which a particle size distribution of a phosphor on a side near the substrate differs from, a particle size distribution of a phosphor on an opposite side, and a particle size of the phosphor on the side near the substrate is larger than a particle size of the phosphor on the opposite side.

Also, in a light-emitting device according to an aspect of the invention, the particle size of the phosphor on the opposite side is 10 μm or smaller.

Also, in a light-emitting device according to an aspect of the invention, a kind of the phosphor on the side near the substrate differs from a kind of the phosphor on the opposite side.

Also, in a light-emitting device according to an aspect of the invention, an emission wavelength of the phosphor on the side near the substrate is longer than an emission wavelength of the phosphor on the opposite side.

Also, in a light-emitting device according to an aspect of the invention, thermal quenching of the phosphor on the side near the substrate is larger than thermal quenching of the phosphor on the opposite side.

Also, in a light-emitting device according to an aspect of the invention, the phosphor (phosphor particles) is deposited on the substrate.

Also, in a light-emitting device according to an aspect of the invention, the semiconductor light-emitting element is a semiconductor laser.

Also, a method for producing a light-emitting device according to an aspect of the invention includes depositing a phosphor having a large particle size on a side near a substrate, and depositing a phosphor having a small particle size on the phosphor having the large particle size by electrophoresis or sedimentation.

### [Additional Matter]

The invention is not limited to the embodiments described above and may be modified in various manners within the scope of the claims, and an embodiment achieved by appropriately combining technical measures disclosed in different embodiments is also included in the technical scope of the invention. Further, by combining the technical measures disclosed in the embodiments, a new technical feature can be formed.

### REFERENCE SIGNS LIST

1 substrate

2 second YAG phosphor (second phosphor)

3 first YAG phosphor (first phosphor)

4 red luminescent phosphor (second phosphor)

5 green luminescent phosphor (first phosphor)

6 reel luminescent phosphor (second phosphor)

7 green luminescent phosphor (first phosphor)

17 projecting lens (projecting part)

61 transmissive substrate (substrate)

10, 20, 30, 40, 50, 60 light-emitting part (light-emitting body)

100, 200 illuminator

105 projecting lens (projecting part)

E1 excitation light

La1 first phosphor layer

La2 second phosphor layer

1. A light-emitting body comprising:
a first phosphor layer containing a first phosphor that receives excitation light and emits first fluorescence; and
a second phosphor layer containing a second phosphor that receives the excitation light and emits second fluorescence,
wherein the first and second phosphor layers are stacked on a substrate,
wherein a particle size of the first phosphor is smaller than a particle size of the second phosphor,
wherein the first phosphor layer is arranged on a side far from the substrate, and the excitation light is incident on the first phosphor layer, and
wherein a material of the first phosphor is same as a material of the second phosphor.

2. A light-emitting body comprising:
a first phosphor layer containing a first phosphor that receives excitation light and emits first fluorescence; and
a second phosphor layer containing a second phosphor that receives the excitation light and emits second fluorescence,
wherein the first and second phosphor layers are stacked on a substrate,
wherein a particle size of the first phosphor is smaller than a particle size of the second phosphor,
wherein the first phosphor layer is arranged on the substrate, and the excitation light is incident on the first phosphor layer, and
wherein a material of the first phosphor is same as a material of the second phosphor.

3. (canceled)

4. The light-emitting body according to claim 1, wherein an emission peak wavelength of the second phosphor is longer than an emission peak wavelength of the first phosphor.

5. The light-emitting body according to claim 2, wherein an emission peak wavelength of the first phosphor is longer than an emission peak wavelength of the second phosphor.

6. The light-emitting body according to claim 1,
wherein the second phosphor layer is arranged on a side near the substrate with respect to the first phosphor layer, and
wherein thermal quenching of the second phosphor is larger than thermal quenching of the first phosphor.

7. The light-emitting body according to claim 2, wherein thermal quenching of the first phosphor is larger than thermal quenching of the second phosphor.

8. A light-emitting device comprising:
an excitation light source that emits the excitation light; and
the light-emitting body according to claim 1.

9. The light-emitting device according to claim 8, wherein the excitation light source is a laser element.

10. An illuminator comprising:
the light-emitting device according to claim 8; and
a projecting part that projects the first fluorescence and the second fluorescence emitted from the light-emitting device.

11. A method for producing the light-emitting body according to claim 1, the method comprising:
stacking the first phosphor and the second phosphor on the substrate by electrophoresis or sedimentation.

12. A light-emitting device comprising:
an excitation light source that emits the excitation light; and
the light-emitting body according to claim 2.
